(19) United States
(12) Patent Application Publication
(10) Pub. No.: US 2020/0082026 A1
(43) Pub. Date: Mar. 12, 2020

(54) GRAPH DATA PROCESSING

(71) Applicant: INTERNATIONAL BUSINESS MACHINES CORPORATION, Armonk, NY (US)

(72) Inventors: Tian Tian, Beijing (CN); Gong Su, New York, NY (US); Qi Liang, Shanghai (CN); Qi Ye, Shanghai (CN); Hong Wei Zhang, Beijing (CN); Weixiong Rao, Shanghai (CN); Guohua Li, Shanghai (CN)

(21) Appl. No.: 16/123,488

(22) Filed: Sep. 6, 2018

(51) Int. Cl. G06F 17/30

(52) U.S. Cl. CPC G06F 17/30958; H03M 7/30; G06F 17/30598; G06F 17/30604

(57) ABSTRACT

Implementations of the present disclosure relate to methods, systems, and computer program products for graph data processing. In one implementation, a computer-implemented method is disclosed. In the method, an adjacency graph of a source graph may be determined by traversing the source graph based on a deep first search rule. Subgraphs may be extracted from the determined adjacency graph based on a predefined shape. Respective subgraph nodes may be built based on nodes in the respective subgraphs. Then the adjacency graph may be updated based on the respective subgraph nodes. In other implementations, a computer-implemented system and a computer program product for graph data processing are disclosed.

### BACKGROUND

The present invention relates generally to the field of computing, and more particularly to data processing. Specifically, the present disclosure relates to methods, systems and products for graph data processing.

Nowadays, graphs are getting more popular in various application environments. As application environments become complicated, scales of the graphs also grow and thus result in a challenge in graph computation. Sometimes, a large scale graph may comprise millions of nodes and tens of millions of edges.

### SUMMARY

Embodiments of the present invention disclose a method, computer system, and a computer program product for data processing. In one aspect, a computer-implemented method is disclosed. According to the method, an adjacency graph of a source graph may be determined by traversing the source graph based on a deep first search rule. Subgraphs may be extracted from the determined adjacency graph based on a predefined shape. Respective subgraph nodes may be built based on nodes in the respective subgraphs. Then the adjacency graph may be updated based on the respective subgraph nodes.

In another aspect, a computer-implemented system is disclosed. The computing system comprises a computer processor coupled to a computer-readable memory unit, where the memory unit comprises instructions that when executed by the computer processor implements a method. According to the method, an adjacency graph of a source graph may be determined by traversing the source graph based on a deep first search rule. Subgraphs may be extracted from the determined adjacency graph based on a predefined shape. Respective subgraph nodes may be built based on nodes in the respective subgraphs. Then the adjacency graph may be updated based on the respective subgraph nodes.

In another aspect, a computer program product is disclosed. The computer program product comprises a computer readable storage medium having program instructions embodied therewith. The program instructions is executable by an electronic device to cause the electronic device to perform actions of: determining an adjacency graph of the source graph by traversing a source graph based on a deep first search rule; extracting subgraphs from the determined adjacency graph based on a predefined shape; building respective subgraph nodes based on nodes in the respective subgraphs; and updating the adjacency graph based on the respective subgraph nodes.

It is to be understood that the summary is not intended to identify key or essential features of implementations of the present disclosure, nor is it intended to be used to limit the scope of the present disclosure. Other features of the present disclosure will become easily comprehensible through the description below.

### BRIEF DESCRIPTION OF THE SEVERAL VIEWS OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1 depicts a cloud computing node according to an embodiment of the present invention;

FIG. 2 depicts a cloud computing environment according to an embodiment of the present invention;

FIG. 3 depicts abstraction model layers according to an embodiment of the present invention;

FIG. 4 depicts an example diagram for processing a source graph according to an embodiment of the present invention;

FIG. 5 depicts an example flowchart of a method for processing a source graph according to an embodiment of the present invention;

FIG. 6 depicts an example diagram for determining an adjacency graph of the source graph based on a deep first search rule according to an embodiment of the present invention;

FIG. 7 depicts an example diagram for extracting a group of subgraphs from the determined adjacency graph according to an embodiment of the present invention;

FIG. 8 depicts an example diagram of a replaced adjacency graph according to an embodiment of the present invention;

FIGS. 9A, 9B and 9C depict example diagrams for updating edges in the replaced adjacency graph according to an embodiment of the present invention;

FIG. 10 depicts an example diagram for traversing the destination graph according to an embodiment of the present invention; and

FIG. 11 depicts an example diagram for clustering the destination graph according to an embodiment of the present invention.

Throughout the drawings, same or similar reference numerals represent the same or similar elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language, Python programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

It is understood in advance that although this disclosure includes a detailed description on cloud computing, implementation of the teachings recited herein are not limited to a cloud computing environment. Rather, embodiments of the present invention are capable of being implemented in conjunction with any other type of computing environment now known or later developed.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. This cloud model may include at least five characteristics, at least three service models, and at least four deployment models.

Characteristics are as follows:

On-demand self-service: a cloud consumer can unilaterally provision computing capabilities, such as server time and network storage, as needed automatically without requiring human interaction with the service's provider.

Broad network access: capabilities are available over a network and accessed through standard mechanisms that promote use by heterogeneous thin or thick client platforms (e.g., mobile phones, laptops, and PDAs).

Resource pooling: the provider's computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but may be able to specify location at a higher level of abstraction (e.g., country, state, or datacenter).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time.

Measured service: cloud systems automatically control and optimize resource use by leveraging a metering capability at some level of abstraction appropriate to the type of service (e.g., storage, processing, bandwidth, and active user accounts). Resource usage can be monitored, controlled, and reported providing transparency for both the provider and consumer of the utilized service.

Service Models are as follows:

Software as a Service (SaaS): the capability provided to the consumer is to use the provider's applications running on a cloud infrastructure. The applications are accessible from various client devices through a thin client interface such as a web browser (e.g., web-based e-mail). The consumer does not manage or control the underlying cloud infrastructure including network, servers, operating systems, storage, or even individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems, or storage, but has control over the deployed applications and possibly application hosting environment configurations.

Analytics as a Service (AaaS): the capability provided to the consumer is to use web-based or cloud-based networks (i.e., infrastructure) to access an analytics platform. Analytics platforms may include access to analytics software resources or may include access to relevant databases, corpora, servers, operating systems or storage. The consumer does not manage or control the underlying web-based or cloud-based infrastructure including databases, corpora, servers, operating systems or storage, but has control over the deployed applications and possibly application hosting environment configurations.

Infrastructure as a Service (IaaS): the capability provided to the consumer is to provision processing, storage, networks, and other fundamental computing resources where the consumer is able to deploy and run arbitrary software, which can include operating systems and applications. The consumer does not manage or control the underlying cloud infrastructure but has control over operating systems, storage, deployed applications, and possibly limited control of select networking components (e.g., host firewalls).

Deployment Models are as follows:

Private cloud: the cloud infrastructure is operated solely for an organization. It may be managed by the organization or a third party and may exist on-premises or off-premises.

Community cloud: the cloud infrastructure is shared by several organizations and supports a specific community that has shared concerns (e.g., mission, security requirements, policy, and compliance considerations). It may be managed by the organizations or a third party and may exist on-premises or off-premises.

Public cloud: the cloud infrastructure is made available to the general public or a large industry group and is owned by an organization selling cloud services.

Hybrid cloud: the cloud infrastructure is a composition of two or more clouds (private, community, or public) that remain unique entities but are bound together by standardized or proprietary technology that enables data and application portability (e.g., cloud bursting for load-balancing between clouds).

A cloud computing environment is service oriented with a focus on statelessness, low coupling, modularity, and semantic interoperability. At the heart of cloud computing is an infrastructure comprising a network of interconnected nodes.

The following described exemplary embodiments provide a system, method and program product for data processing. As such, the present embodiment has the capacity to improve the technical field of data processing by reducing the scale of the graph and increasing the graph computation in a fast and convenient way. More specifically, the invention operates a graph computation directly on a compressed graph with non-decompression or partial decompression, cluster the graph before compression and encode the clustered graph to reduce the graph size (e.g., compression).

As previously described, nowadays, graphs are getting more popular in various application environments. As application environments become complicated, scales of the graphs also grow and thus result in a challenge in graph computation. Sometimes, a large scale graph may comprise millions of nodes and tens of millions of edges. At this point, how to reduce the scale the graph and increase the graph computation in a fast and convenient way becomes a focus.

Therefore, it may be advantageous to, among other things, utilize compression to cut the space cost of large-scale graphs, since compression may reduce graph size to fit in memory and thus help to reduce overhead of the Input/Output (I/O) operation. In addition, the optimization of computation may lay on the I/O efficiency and query process. Decompression may be necessary when adopting some compression approach (e.g., zip), and may comprise the I/O reduction achieved by compression. As such, to save time, non-decompression or partial decompression may be utilized, if possible. Furthermore, indexing may be useful to reduce the querying time.

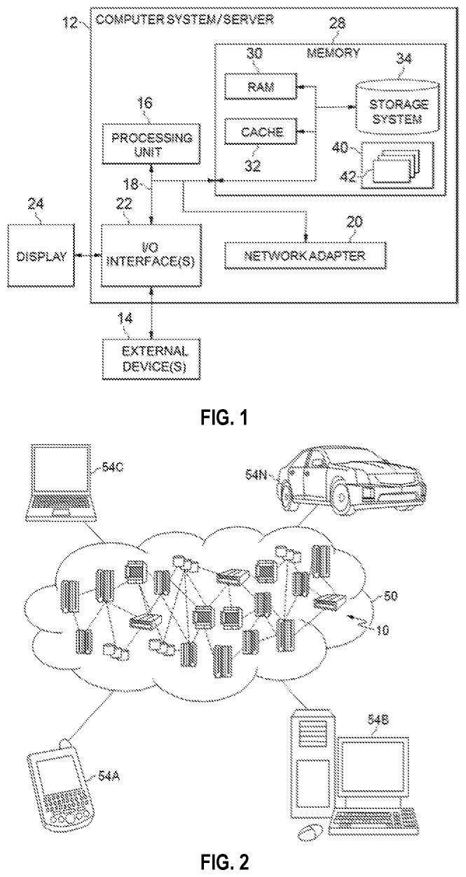

Referring now to FIG. 1, a schematic of an example of a cloud computing node is shown. Cloud computing node is only one example of a suitable cloud computing node and is not intended to suggest any limitation as to the scope of use or functionality of embodiments of the invention described herein. Regardless, cloud computing node is capable of being implemented and/or performing any of the functionality set forth hereinabove.

In cloud computing node, there is a computer system/server 12 or a portable electronic device such as a communication device, which is operational with numerous other general purpose or special purpose computing system environments or configurations. Examples of well-known computing systems, environments, and/or configurations that may be suitable for use with computer system/server 12 include, but are not limited to, personal computer systems, server computer systems, thin clients, thick clients, hand-held or laptop devices, multiprocessor systems, microprocessor-based systems, set top boxes, programmable consumer electronics, network PCs, minicomputer systems, mainframe computer systems, and distributed cloud computing environments that include any of the above systems or devices, and the like.

Computer system/server 12 may be described in the general context of computer system-executable instructions, such as program modules, being executed by a computer system. Generally, program modules may include routines, programs, objects, components, logic, data structures, and so on that perform particular tasks or implement particular abstract data types. Computer system/server 12 may be practiced in distributed cloud computing environments where tasks are performed by remote processing devices that are linked through a communications network. In a distributed cloud computing environment, program modules may be located in both local and remote computer system storage media including memory storage devices.

As shown in FIG. 1, computer system/server 12 in cloud computing node is shown in the form of a general-purpose computing device. The components of computer system/server 12 may include, but are not limited to, one or more processors or processing units 16, a system memory 28, and a bus 18 that couples (i.e., combines) various system components including system memory 28 to processor 16.

Bus 18 represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus.

Computer system/server 12 typically includes a variety of computer system readable media. Such media may be any available media that is accessible by computer system/server 12, and it includes both volatile and non-volatile media, removable and non-removable media.

System memory 28 can include computer system readable media in the form of volatile memory, such as random access memory (RAM) 30 and/or cache memory 32. Computer system/server 12 may further include other removable/non-removable, volatile/non-volatile computer system storage media. By way of example only, storage system 34 can be provided for reading from and writing to a non-removable, non-volatile magnetic media (not shown and typically called a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or another optical media can be provided. In such instances, each can be connected to bus 18 by one or more data media interfaces. As will be further depicted and described below, memory 28 may include at least one program product having a set (e.g., at least one) of program modules that are configured to carry out the functions of embodiments of the invention.

Program/utility 40, having a set (at least one) of program modules 42, may be stored in memory 28 by way of example, and not limitation, as well as an operating system, one or more application programs, other program modules, and program data. Each of the operating system, one or more application programs, other program modules, and program data or some combination thereof, may include an implementation of a networking environment. Program modules 42 generally carry out the functions and/or methodologies of embodiments of the invention as described herein.

Computer system/server 12 may also communicate with one or more external devices 14 such as a keyboard, a pointing device, a display 24, etc.; one or more devices that enable a user to interact with computer system/server 12; and/or any devices (e.g., network card, modem, etc.) that enable computer system/server 12 to communicate with one or more other computing devices. Such communication can occur via Input/output (I/O) interfaces 22. Still yet, computer system/server 12 can communicate with one or more networks such as a local area network (LAN), a general wide area network (WAN), and/or a public network (e.g., the Internet) via network adapter 20. As depicted, network adapter 20 communicates with the other components of computer system/server 12 via bus 18. It should be understood that although not shown, other hardware and/or software components could be used in conjunction with computer system/server 12. Examples, include, but are not limited to: microcode, device drivers, redundant processing units, external disk drive arrays, RAID systems, tape drives, and data archival storage systems, etc.

Referring now to FIG. 2, illustrative cloud computing environment 50 is depicted. As shown, cloud computing environment 50 comprises one or more cloud computing nodes 10 with which local computing devices used by cloud consumers, such as, for example, personal digital assistant (PDA) or cellular telephone 54A, desktop computer 54B, laptop computer 54C, and/or automobile computer system 54N may communicate. Nodes 10 may communicate with one another. They may be grouped (not shown) physically or virtually, in one or more networks, such as Private, Community, Public, or Hybrid clouds as described hereinabove, or a combination thereof. This allows cloud computing environment 50 to offer infrastructure, platforms and/or software as services for which a cloud consumer does not need to maintain resources on a local computing device. It is understood that the types of computing devices 54A-N shown in FIG. 2 are intended to be illustrative only and that computing nodes 10 and cloud computing environment 50 can communicate with any type of computerized device over any type of network and/or network addressable connection (e.g., using a web browser).

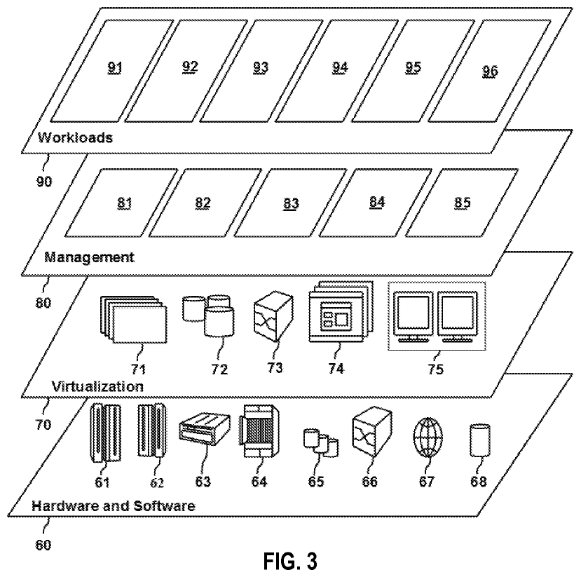

Referring now to FIG. 3, a set of functional abstraction layers provided by cloud computing environment 50 (FIG. 2) is shown. It should be understood in advance that the components, layers, and functions shown in FIG. 3 are intended to be illustrative only and embodiments of the invention are not limited thereto. As depicted, the following layers and corresponding functions are provided:

Hardware and software layer 60 includes hardware and software components. Examples of hardware components include: mainframes 61; RISC (Reduced Instruction Set Computer) architecture based servers 62; servers 63; blade servers 64; storage devices 65; and networks and networking components 66. In some embodiments, software components include network application server software 67 and database software 68.

Virtualization layer 70 provides an abstraction layer from which the following examples of virtual entities may be provided: virtual servers 71; virtual storage 72; virtual networks 73, including virtual private networks; virtual applications and operating systems 74; and virtual clients 75.

In one example, management layer 80 may provide the functions described below. Resource provisioning 81 provides dynamic procurement of computing resources and other resources that are utilized to perform tasks within the cloud computing environment. Metering and Pricing 82 provide cost tracking as resources are utilized within the cloud computing environment, and billing or invoicing for consumption of these resources. In one example, these resources may include application software licenses. Security provides identity verification for cloud consumers and tasks, as well as protection for data and other resources. User portal 83 provides access to the cloud computing environment for consumers and system administrators. Service level management 84 provides cloud computing resource allocation and management such that required service levels are met. Service Level Agreement (SLA) planning and fulfillment 85 provides pre-arrangement for, and procurement of, cloud computing resources for which a future requirement is anticipated in accordance with an SLA.

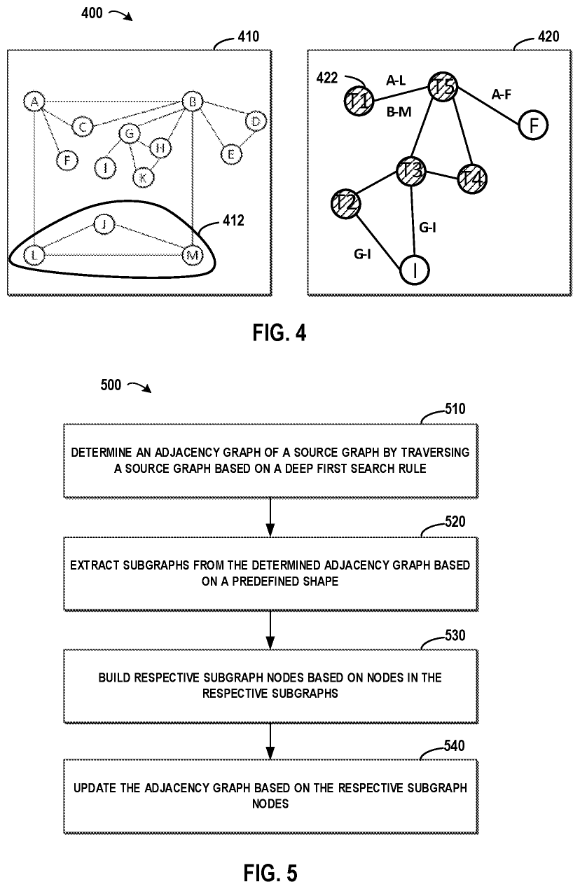

Workloads layer 90 provides examples of functionality for which the cloud computing environment may be utilized. Examples of workloads and functions which may be provided from this layer include: mapping and navigation 91; software development and lifecycle management 92; virtual classroom education delivery 93; data analytics processing 94; transaction processing 95; and graph data processing 96. Hereinafter, reference will be made to FIGS. 4 to 11 to describe details of the graph processing 96.

Graphs are widely used in various environments. For example, a social network that describes various users and association relationships among the users may be represented by a graph, where a node in the graph may indicate a user and an edge between two nodes may indicate an association between the two users indicated by the two nodes. For another example, in a graph representing a geographic information system, a node may indicate an intersection, and an edge may indicate a road between two intersections. For the sake of description, implementations of the present disclosure will be described in an environment of a social network. In the social network, the association between two users may indicate that the users know each other. Although the present disclosure describes implementations by an example graph representing the social network, in another implementation, the graph may represent another application environment such as a topology of a city road network or a communication network.

There have been provided several approaches in the field of graph data processing. According to one approach, the graph may be compressed to reduce the data amount of the graph. Although this approach may lower the data amount for storing the graph, before the compressed graph is accessed, the compressed graph should be subject to a decompressing procedure to recover the original graph. In this situation, the decompressing procedure will result in extra computation and Input/Output overhead. According to another approach, the graph may be divided into various portions and these portions may be compressed separately. Although this approach may avoid decompressing the whole graph and may only needs to decompress a target portion of the graph, extra overhead may be caused in coordinating the various portions.

In order to at least partially solve the above and other potential problems, a new method for processing a graph is disclosed according to implementations of the present disclosure. Hereinafter, reference will be made to FIG. 4 for a general description of the present disclosure. FIG. 4 depicts an example diagram 400 for processing a source graph 410 according to an embodiment of the present invention. As shown in FIG. 4, the source graph 410 may be converted into a destination graph 420. Referring to the source graph 410, there are a plurality of nodes and edges. Here, the nodes A-M may indicate various users in the social network, and the edges may indicate associations between the users.

Here, the source graph 410 may be converted into a destination graph 420, where a group of subgraphs with a predefined shape (such as a triangle) in the source graph 410 may be replaced with respective subgraph nodes (as shown in shaded patterns) in the destination graph 420. For example, a triangle 412 which is a subgraph comprising the nodes L, J, M may be replaced by a node T1 with a reference number 422 in the destination graph 420. Similarly, other subgraphs may be replaced by other nodes T2, T3, T4 and T5 to form the destination graph 420. With this implementation, by replacing subgraphs that comprising multiple nodes in the source graph with respective subgraph nodes, the source graph 410 having a great number of nodes may be converted to the destination graph 420 that have a reduced number of nodes and edges. Therefore, the complexity of the source graph 410 may be simplified, which may result in a more efficient performance in the graph computation. Having provided a general description of the implementations, reference will be made to FIG. 5 for details about how to convert the source graph 410 into the destination graph 420.

FIG. 5 depicts an example flowchart of a method 500 for processing a source graph 410 according to an embodiment of the present invention. At a block 510, an adjacency graph of the source graph 410 may be determined by traversing the source graph 410 based on a deep first search (DFS) rule. Here, the DFS is an algorithm for traversing a graph data structure. The traversing may start at a beginning node and explores as far as possible along each branch before backtracking. In this implementation, an arbitrary node in the source graph 410 may be selected as the beginning node.

At a block 520, subgraphs may be extracted from the determined adjacency graph based on shapes of the subgraphs. In according to an embodiment of the present invention, the subgraphs may be extracted based on a predefined shape. In the present disclosure, details of the implementations will be described by taking a triangle as an example of the subgraph. It is to be understood that the predefined shape may include a triangle, a square, or a connected square. Here, the connected square may refer to a square where all the four nodes in the square are connected with edges. Based on the descriptions about the triangle subgraph, details about the implementation when the subgraph has another shape may be determined by those skilled in the art.

Once the adjacency graph is determined, the adjacency graph may be searched to determine the subgraphs. Depending on the application environment of the graph, the shape of the subgraph may be selected differently. For example, if the source graph 410 represents the social network, then a triangle may be selected because the relationship indicated by a triangle in the graph (where three users shown by the triangle know each other) is very common in the social network. In another example, if the source graph 410 represents the road network in a city, a square may be selected as the subgraph because most of the road network around a block in the city shows a square pattern.

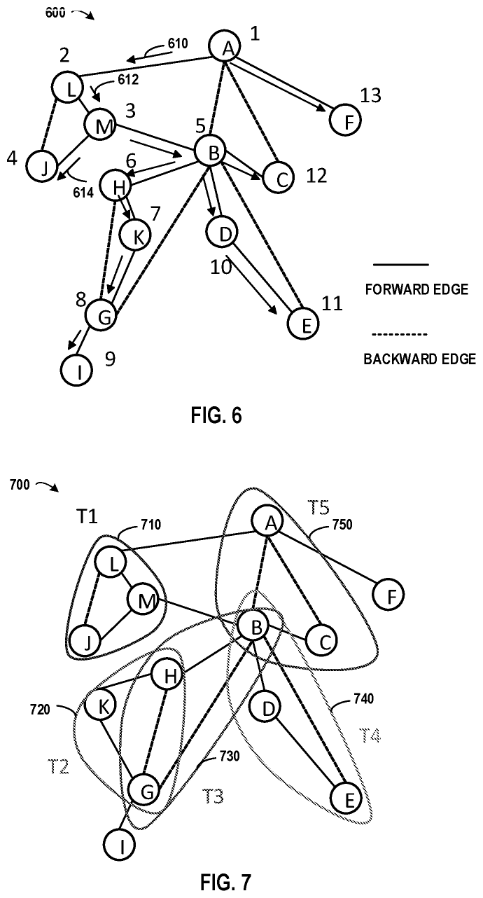

At a block 530, respective subgraph nodes may be built based on nodes in the respective subgraphs. Here, the association relationship between the subgraph nodes and nodes in the subgraph may be recorded. Referring back to FIG. 4, the subgraph node “T1” may be associated with three nodes J, L, and M. Then, at a block 540, the adjacency graph may be updated based on the respective subgraph nodes to form the updated adjacency graph. Hereinafter, the updated adjacency graph that is generated according to implementations of the present disclosure may be called the destination graph 420. Hereinafter, reference will be made to FIG. 6 for describing how to determine the adjacent graph of the source graph 410.

FIG. 6 depicts an example diagram for determining an adjacency graph 600 of the source graph 410 based on a deep first search rule according to an embodiment of the present invention. In FIG. 6, the nodes A to M have the same meaning as those in the source graph 410. In other words, the nodes A to M in the adjacency graph 600 also represent the users in the social network. The edge in the adjacency graph 600 indicates that there is an association between users at two ends of the edge, where the line style of the edge indicates the direction during traversing the source graph 410. A solid line indicates a forward edge, which means the edge is obtained when going through the source graph 410 in a forward direction. A dashed line indicates a backward edge, which means the edge is obtained when backtracking in the source graph 410 in a backward direction.

Here, the number near a given node in the adjacency graph 600 is a sequence number indicating when the given node is reached based on the DFS rule. For example, the traversing starts at the node A, and thus the node A is the first node reached in the traversing, where the node A is labeled by a sequence number “1.” Then, based on the DFS rule, the traversing goes along an arrow 610, and then the node L is the second one reached in the traversing, where the node L is labeled by a sequence number “2.” Next, nodes M, J may be reached subsequently along arrows 612 and 614. As the above nodes are reached in going through the source graph 410 in the forward direction, the edges between the nodes A, L, M and J are shown by the solid lines. After the node J, based on the DFS rule, the node L is the next node reached in the backtracking, and thus the edge between the nodes J and L are shown by the dashed line. Based on the DFS rule, the source graph 410 may be traversed and the adjacency graph 600 may be determined.

In according to an embodiment of the present invention, with respect to one subgraph in the group of subgraphs, a relationship among edges in the subgraph may be determined based on the shapes of the subgraphs. Next, the adjacency graph may be traversed to determine edges satisfying the relationship, and then a subgraph may be extracted based on the group of edges. With this implementation, the extracting the subgraph may be simplified into an easy procedure, where the edges that satisfy the relationship for defining the subgraph may be found by traversing the adjacency graph.

Hereinafter, reference will be made to FIG. 7 for providing how to extract the subgraph from the adjacency graph 600. FIG. 7 depicts an example diagram 700 for extracting a group of subgraphs from the determined adjacency graph 600 according to an embodiment of the present invention. Referring to FIG. 7, the arrows and sequence numbers in FIG. 6 are removed, and areas 710, 720, 730, 740 and 750 indicate subgraphs in the adjacency graph. In this implementation, a relationship among edges in a subgraph in the group of subgraphs may be determined based on the shapes of the subgraphs.

With respect to a triangle, the relationships may be: (1) if the subgraph is defined by two forward edges and one backward edge, then the subgraph may be determined as a triangle; and (2) if the subgraph is defined by one forward edge and two backward edges, then the subgraph may be determined as a triangle. The adjacency graph 600 may be traversed to determine edges satisfying the relationship, and then the subgraph(s) based on may be determined based on the determined edges. Referring to FIG. 6, triangles L-M-J, H-K-G, and B-D-E may be identified based on the above relationship (1); and triangles A-B-C and B-H-G may be identified based on the above relationship (2). In another implementation, the above relationships may be summarized as if the nodes of one backward edge have common neighbor node, then these three nodes may construct a triangle.

Referring to FIG. 7, three nodes L, J and M are comprised in the area 710, where the edge between the nodes L and M is a forward edge, the edge between the nodes M and J is also a forward edge, and the edge between the nodes L and J is a backward edge. At this point, the three edges in the area 710 satisfy the above relationship, and then these three edges may be considered as edges of a triangle subgraph. Therefore, the triangle T1 which comprises the three nodes L, M and J may be extracted. Based on similar procedure, the triangles T2, T3, T4 and T5 may also be extracted from the areas 720, 730, 740 and 750 because each of these triangles comprises two forward edges and one backward edge.

In according to an embodiment of the present invention, a node association may be built for describing relationship between the respective subgraph nodes and regular nodes. Here, the node association may be stored in various data structures such as a table, a list, an array and the like. In one implementation, the following Table 1 may be adapted for storing the node association. Hereinafter, in order to highlight the difference between the subgraph node and the node that exists in the original adjacency graph 600, the latter node may be called as a regular node.

TABLE 1
Example of Node Association

| No. | Subgraph Node | Regular Node |
|---|---|---|
| 1 | T1 | J, L, M |
| 2 | T2 | G, H, K |
| 3 | T3 | B, G, H |
| 4 | T4 | B, D, E |
| 5 | T5 | A, B, C |

In the above Table 1, the first column may indicate the serial number of the subgraph, the second column may indicate the identification of the subgraph node, and the third column may indicate regular nodes comprised in the subgraph corresponding to the subgraph node. The first entry in Table 1 shows the situation of the subgraph in the area 710 in FIG. 7. Here, the identification of the subgraph node is “T1”, and the subgraph corresponding to the subgraph node “T1” comprises three nodes J, L, and M. Further, the second entry in Table 1 shows the situation of the subgraph in the area 720 in FIG. 7, where the subgraph node “T2” is associated with three nodes G, H, and K.

In according to an embodiment of the present invention, the updating the adjacency graph 600 may relate to updating both of the nodes and the edges in the adjacency graph 600. First, the respective subgraphs in the adjacency graph 600 may be replaced with the respective subgraph nodes as shown in Table 1. Then, edges in the replaced adjacency graph may be updated based on edges between regular nodes in the adjacency graph 600 to form the destination graph 420.

With this implementation, as the respective subgraphs are replaced with the respective subgraph nodes, the number of the nodes in the replaced adjacency graph may be greatly reduced. Taking the triangle as the example of the subgraph, the number of the subgraph nodes may be reduced to about ⅓ of the number of the nodes that are originally comprised in the subgraphs. In another implementation where the subgraph is a square, the number of the subgraph nodes may be reduced to about ¼ of the number of the original number. Clearly, the present implementation may lower the number of the nodes in the destination graph 420 significantly.

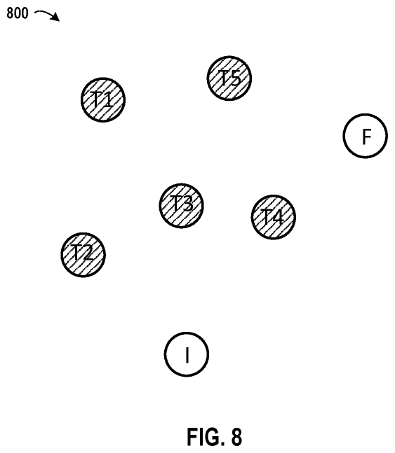

In order to update the nodes, the subgraphs in the adjacency graph 600 may be replaced with the respective subgraph nodes. Still referring to FIG. 7, the subgraph in the area 710 may be replaced with the subgraph node T1, the subgraph in the area 720 may be replaced with the subgraph node T2. For other subgraphs within the areas 730, 740 and 750, they may be replaced with the subgraph nodes T3, T4 and T5, respectively. FIG. 8 depicts an example diagram of a replaced adjacency graph 800 according to an embodiment of the present invention, here, edges between the subgraph nodes (such as the subgraph nodes T1 to T5) and regular nodes (such as the nodes F and I) may be removed to form the replaced adjacency graph 800 in FIG. 8.

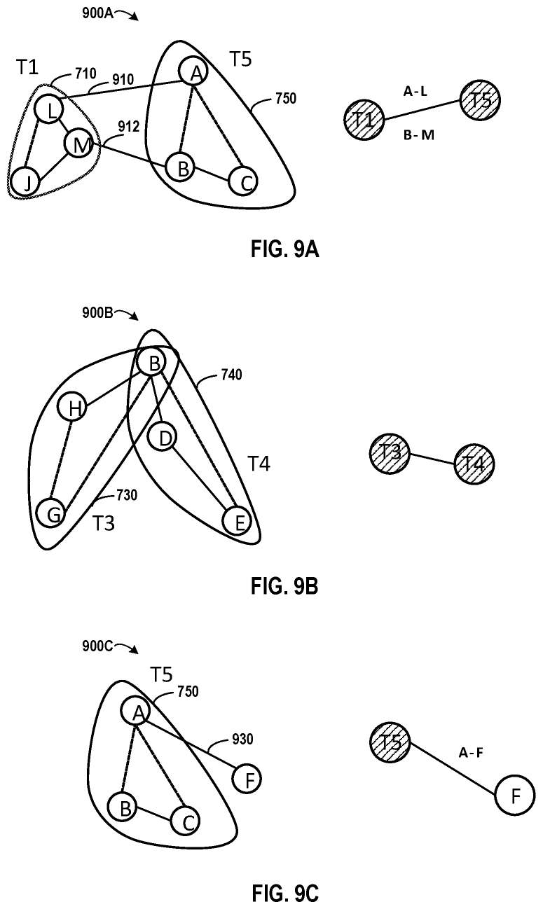

Once the respective subgraphs are replaced with the respective subgraph nodes, edges in the replaced adjacency graph 800 may be updated. Reference will be made to FIGS. 9A, 9B and 9C for various aspects for the updating procedure. In according to an embodiment of the present invention, the updating edges in the replaced adjacency graph may relate to various aspects. In one aspect, edges between two subgraph nodes may be determined. In another aspect, edges between a subgraph node and a regular node that exists in the original adjacency graph may be determined. In a further aspect, edges between regular nodes that exist in the original adjacency graph 600 may remain the original situation. With this implementation, as the edges within respective subgraphs are not comprised in the destination graph any more, the number of the edges in the destination graph 420 is also reduced. Compared with the source graph 410, the scale of the destination graph 420 may be significantly compressed.

In according to an embodiment of the present invention, with respect to a first subgraph node and a second subgraph node in the replaced adjacency graph, an edge may be added between the first subgraph node and the second subgraph node in response to an edge existing between a node comprised in a first subgraph indicated by the first subgraph node and a node comprised in a second subgraph indicated by the second subgraph node. Reference will be made to FIG. 9A to describe the above situation.

FIG. 9A shows an example diagram 900A comprising two portions: the left side shows a portion of the adjacency graph 700 which comprises a subgraph in the area 710 and a subgraph in the area 750; and the right side shows a corresponding portion of the destination graph 420. After the two subgraphs are replaced by the subgraph nodes T1 and T5, edges related to the two subgraphs may be updated. Referring to the left side of FIG. 9A, there is an edge 910 between the nodes A and L, therefore an edge A-L may be added between the subgraph nodes Ti and T5 at the right side. Further, there is an edge 912 between the nodes B and M, and thus an edge B-M may be added between the subgraph nodes T1 and T5.

In according to an embodiment of the present invention, with respect to a first subgraph node and a second subgraph node in the replaced adjacency graph, an edge may be added between the first subgraph node and the second subgraph node in response to a node being shared by a first subgraph indicated by the first subgraph node and a second subgraph indicated by the second subgraph node. Reference will be made to FIG. 9B to describe the above situation.

FIG. 9B shows an example diagram 900B comprising two portions: the left side shows a portion of the adjacency graph 700 which comprises a subgraph in the area 730 and a subgraph in the area 740; and the right side shows a corresponding portion of the destination graph 420. After the two subgraphs are replaced by the subgraph nodes T3 and T4, edges related to the two subgraphs may be updated. Referring to the left side of FIG. 9B, the two subgraphs shown in the areas 730 and 740 share a same node B, therefore an edge may be added between the subgraph nodes T3 and T4.

In according to an embodiment of the present invention, with respect to a subgraph node and a regular node in the replaced adjacency graph, an edge may be added between the subgraph node and the regular node in response to the regular node being connected to a node comprised a subgraph indicated by the subgraph node. Reference will be made to FIG. 9C to describe the above situation.

FIG. 9C shows an example diagram 900C comprising two portions: the left side shows a portion of the adjacency graph 700 which comprises a subgraph in the area 750 and a regular node F which exists in the original adjacency graph 600; and the right side shows a corresponding portion of the destination graph 420. After the subgraph is replaced by the subgraph node T5, edges related to the two subgraphs may be updated. Referring to the left portion of FIG. 9C, there is an edge 930 between the nodes A and F, therefore an edge A-F may be added between the subgraph node T5 and the regular node F.

Based on the procedures described in the above paragraphs, edges in the replaced graph 800 as shown in FIG. 8 may be updated to form the destination graph 420. In according to an embodiment of the present invention, the edges in the destination graph may be recorded in various data structure so as to accelerate the further graph computation. Specifically, a first edge set may be built for describing relationship between the respective subgraph nodes; and a second edge set may be built for describing relationship between the respective subgraph nodes and the regular nodes. Here, the node sets may be stored in various data structures such as a table, a list, an array and the like. In one implementation, the following Tables 2 and 3 may be adapted for storing the first and second edge sets, respectively.

TABLE 2
Example of First Edge Set

| No. | Edge between Subgraph Nodes | Type of Edge |
|---|---|---|
| 1 | T1-T5 | A-L, B-M |
| 2 | T3-T5 | Common Node B |
| 3 | T4-T5 | Common Node B |
| 4 | T2-T3 | Common Nodes H and G |
| 5 | T3-T4 | Common Node B |

In the above Table 2, the first column may indicate the serial number of the edge, the second column may indicate two ends of the edge, and the third column may indicate the type of the edge. Taking the first entry in Table 2 as an example, edges exist between the subgraph nodes T1 and T5. The edges comprise two edges: one edge is between the regular nodes A and L; and another edge is between the regular nodes B and M. Taking the second entry in Table 2 as an example, one edge exists between the subgraph nodes T3 and T5 because the two subgraph nodes T3 and T5 share a common node B.

TABLE 3
Example of Second Edge Set

| No. | Edge between Regular Nodes |
|---|---|
| 1 | A-F |
| 2 | G-I |

In the above Table 3, the first column may indicate the serial number of the edge, and the second column may indicate two ends of the regular edge. Taking the first entry in Table 3 as an example, an edge exists between the regular nodes A and F. It is to be understood that the above Tables 2 and 3 are only example data structures for storing the edges between subgraph nodes and the regular nodes. In another implementation, another data structure such as an array may be adopted.

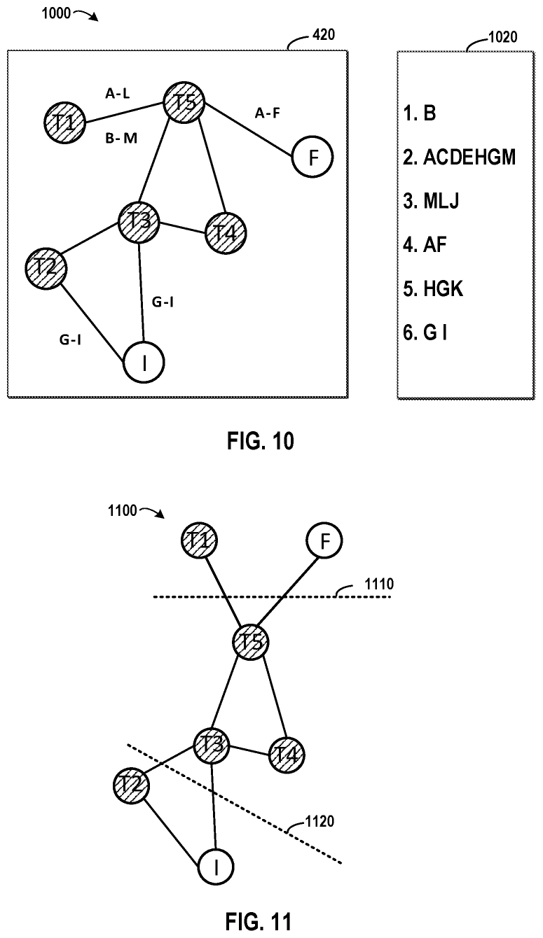

The above paragraphs have described the detailed implementation about how to convert the source graph 410 into the destination graph 420. Hereinafter, reference will be made to FIGS. 9A, 9B, 9C, and 10 to describe details about further operations that may be made to the destination graph 420. In according to an embodiment of the present invention, a request to the source graph 410 may be converted to a request to the destination graph 420. It is to be understood that operations such as traversing and clustering may be made to the destination graph 420 directly based on searching in the above three tables. It is to be understood that the searching operation may be much effective than the decompressing operation which is an essential step in a traditional solution.

In according to an embodiment of the present invention, the destination graph 420 may be traversed from a beginning node specified by the request. If the beginning node is a subgraph node, nodes in a subgraph indicated by the subgraph node may be traversed based on the node association. Then, the traversing may move to a next node from the beginning node based on the first edge set and the second edge set.

FIG. 10 depicts an example diagram 1000 for traversing the destination graph 420 according to an embodiment of the present invention. Supposing the beginning node is specified as the node B, the traversing may start at the node B. As shown in a traversing path 1020, the node B is reached in the first round during the traversing procedure. Based on Table 1, it may be determined that the node B is comprised in the subgraphs indicated by the subgraph nodes T5, T4 and T3, therefore nodes comprised in subgraphs indicated by the subgraph node T5, T4 and T3 may be traversed. From Table 1, the subgraph indicated by the subgraph node T5 comprises Nodes A, B and C; the subgraph indicated by the subgraph node T4 comprises Nodes B, D and E; and the subgraph indicated by the subgraph node T3 comprises Nodes B, G and H. Therefore, in the second round of the traversing procedure, the nodes A, C, D, E, H and G may be reached. Further, according to Table 2, there is an edge B-M between the subgraphs T5 comprising the beginning node B and T1, the traversing may move to the next node M from the beginning node B. At this point, the node M may also be reached in the second round.

Hereinafter, the traversing may start from the node M and details of the procedure may be similar as those when the traversing starts from the beginning node B. In according to an embodiment of the present invention, if the beginning node is a regular node, the traversing may move to a next node from the beginning node based on the second edge set. In one example, if the node F is determined as the beginning node, the node A may be determined as the next node based on Table 3. After several rounds, the traversing path 1020 may comprise the nodes as shown in FIG. 10 and all the nodes in the source graph 410 may be reached. Although the above traversing procedure is based on a Broad First Search (BFS) rule, other traversing procedure rule like DFS may be adopted and those skilled in the art may work out a traversing path based on the adopted rule.

In according to an embodiment of the present invention, a request for clustering nodes in the source graph may be converted into a request for clustering nodes in the destination graph. Here, the nodes (comprising the subgraph nodes and regular nodes) in the destination graph 420 may be clustered based on the first edge set and the second edge set. Reference will be made to FIG. 11 which depicts an example diagram 1100 for clustering the destination graph 420 according to an embodiment of the present invention.

Usually, the clustering operation is based on the closeness between nodes. As nodes in the subgraph often have great closeness degree, these nodes should be clustered into a same classification. Based on this, the subgraph nodes in the destination graph 420 may be considered regular nodes and the all the nodes in the destination graph 420 may be clustered based on closeness degrees among them. Referring to FIG. 11, the destination graph 420 may be cut along lines 1110 and 1120. Therefore, the subgraph node T2 and the regular node I may be clustered into a first classification, the subgraph nodes T3, T4 and T5 may be clustered into a second classification, and the subgraph node T1 and the regular node F may be clustered into a third classification.

It is to be understood that the above paragraphs have described implementations by taking an undirected graph as the source graph 410. In another implementation, the source graph 410 may be a directed graph. At this point, during traversing the source graph 410, nodes in the source graph 410 may be reached along the direction of the edge. Further, the relationship among edges in a subgraph may be determined based on both the shape and the direction of the edges in the subgraph. Based on the description of the present disclosure, those skilled in the art may modify the implementations for an undirected graph to a directed graph.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method for graph data processing, the method comprising:
determining an adjacency graph of a source graph by traversing the source graph based on a deep first search rule;
extracting one or more subgraphs from the determined adjacency graph based on a predefined shape;
building a plurality of subgraph nodes based on one or more nodes in the extracted one or more subgraphs; and
updating the adjacency graph based on the built plurality of subgraph nodes.

2. The method of claim 1, further comprising:
determining a relationship among a plurality of subgraph edges associated with the extracted one or more subgraphs based on one or more shapes associated with the extracted one or more subgraphs;
determining the plurality of subgraph edges satisfying the determined relationship from the determined adjacency graph; and
utilizing the determined plurality of subgraph edges to extract the one or more subgraphs.

3. The method of claim 1, wherein updating the adjacency graph based on the built plurality of subgraph nodes, further comprises:
replacing the extracted one or more subgraphs in the determined adjacency graph with the built plurality of subgraph nodes; and
updating the determined plurality of subgraph edges associated with the replaced adjacency graph based on the determined plurality of subgraph edges between a plurality of regular nodes associated with the determined adjacency graph, wherein the determined plurality of subgraph edges associated with the replaced adjacency includes a first subgraph node associated with the replaced adjacency graph and a second subgraph node associated with the replaced adjacency graph, wherein the determined adjacency graph is updated.

4. The method of claim 3, further comprising:
in response to an edge existing between a first node comprised in a first subgraph indicated by the first subgraph node and a second node comprised in a second subgraph indicated by the second subgraph node, adding a first edge between the first subgraph node associated with the replaced adjacency graph and the second subgraph node associated with the replaced adjacency graph.

5. The method of claim 3, further comprising:
in response to a first node being shared by a first subgraph indicated by the first subgraph node and a second subgraph indicated by the second subgraph node, adding a first edge between the first subgraph node and the second subgraph node.

6. The method of claim 3, further comprising:
in response to the regular node associated with the plurality of regular nodes being connected to a first node in a subgraph indicated by the subgraph node, adding a first edge between the subgraph node and the regular node.

7. The method of claim 3, further comprising:
building at least one node association for describing a relationship between the built plurality of subgraph nodes and the plurality of regular nodes;
building a first edge set for describing the relationship between the built plurality of subgraph nodes; and
building a second edge set for describing the relationship between the built plurality of subgraph nodes and the plurality of regular nodes.

8. The method of claim 7, further comprising:
receiving a request for traversing a source graph from a beginning node;
in response to the beginning node being a subgraph node, traversing nodes associated with the extracted one or more subgraph indicated by the subgraph node based on the node association, and moving to a next node from the beginning node based on the first edge set and the second edge set; and
in response to the beginning node being the regular node, moving to a next node from the beginning node based on the second edge set.

9. The method of claim 8, further comprising:
in response to receiving a second request for clustering nodes in the source graph, clustering the built plurality of subgraph nodes and the plurality of regular nodes in the updated adjacency graph based on the first edge set and the second edge set.

10. The method of claim 1, wherein the predefined shape comprises at least one of the following:
(i) a triangle;
(ii) a square; and
(iii) a connected square.

11. A computer system for graph data processing, comprising:
one or more processors, one or more computer-readable memories, one or more computer-readable tangible storage medium, and program instructions stored on at least one of the one or more tangible storage medium for execution by at least one of the one or more processors via at least one of the one or more memories, wherein the computer system is capable of performing a method comprising:
determining an adjacency graph of a source graph by traversing the source graph based on a deep first search rule;
extracting one or more subgraphs from the determined adjacency graph based on a predefined shape;
building a plurality of subgraph nodes based on one or more nodes in the extracted one or more subgraphs; and
updating the adjacency graph based on the built plurality of subgraph nodes.

12. The computer system of claim 11, further comprising:
determining a relationship among a plurality of subgraph edges associated with the extracted one or more subgraphs based on one or more shapes associated with the extracted one or more subgraphs;
determining the plurality of subgraph edges satisfying the determined relationship from the determined adjacency graph; and
utilizing the determined plurality of subgraph edges to extract the one or more subgraphs.

13. The computer system of claim 11, wherein updating the adjacency graph based on the built plurality of subgraph nodes, further comprises:
replacing the extracted one or more subgraphs in the determined adjacency graph with the built plurality of subgraph nodes; and
updating the determined plurality of subgraph edges associated with the replaced adjacency graph based on the determined plurality of subgraph edges between a plurality of regular nodes associated with the determined adjacency graph, wherein the determined plurality of subgraph edges associated with the replaced adjacency includes a first subgraph node associated with the replaced adjacency graph and a second subgraph node associated with the replaced adjacency graph, wherein the determined adjacency graph is updated.

14. The computer system of claim 13, further comprising:
in response to an edge existing between a first node comprised in a first subgraph indicated by the first subgraph node and a second node comprised in a second subgraph indicated by the second subgraph node, adding a first edge between the first subgraph node associated with the replaced adjacency graph and the second subgraph node associated with the replaced adjacency graph.

15. The computer system of claim 13, further comprising;
in response to a first node being shared by a first subgraph indicated by the first subgraph node and a second subgraph indicated by the second subgraph node, adding a first edge between the first subgraph node and the second subgraph node.

16. The computer system of claim 13, further comprising:
in response to the regular node associated with the plurality of regular nodes being connected to a first node in a subgraph indicated by the subgraph node, adding a first edge between the subgraph node and the regular node.

17. The computer system of claim 13, further comprising:
building at least one node association for describing a relationship between the built plurality of subgraph nodes and the plurality of regular nodes;
building a first edge set for describing the relationship between the built plurality of subgraph nodes; and
building a second edge set for describing the relationship between the built plurality of subgraph nodes and the plurality of regular nodes.

18. The computer system of claim 17, further comprising:
receiving a request for traversing a source graph from a beginning node;
in response to the beginning node being a subgraph node, traversing nodes associated with the extracted one or more subgraph indicated by the subgraph node based on the node association, and moving to a next node from the beginning node based on the first edge set and the second edge set; and
in response to the beginning node being the regular node, moving to a next node from the beginning node based on the second edge set.

19. The computer system of claim 18, further comprising:
in response to receiving a second request for clustering nodes in the source graph, clustering the built plurality of subgraph nodes and the plurality of regular nodes in the updated adjacency graph based on the first edge set and the second edge set.

20. A computer program product for graph data processing, comprising:
one or more computer-readable storage media and program instructions stored on at least one of the one or more tangible storage media, the program instructions executable by a processor to cause the processor to perform a method comprising:
determining an adjacency graph of a source graph by traversing the source graph based on a deep first search rule;
extracting one or more subgraphs from the determined adjacency graph based on a predefined shape;
building a plurality of subgraph nodes based on one or more nodes in the extracted one or more subgraphs; and
updating the adjacency graph based on the built plurality of subgraph nodes.
